(19) United States
(12) Patent Application Publication
(10) Pub. No.: US 2024/0419087 A1
(43) Pub. Date: Dec. 19, 2024

(54) SUBSTRATE CHUCK, LITHOGRAPHY APPARATUS, AND ARTICLE MANUFACTURING METHOD

(71) Applicant: CANON KABUSHIKI KAISHA, Tokyo (JP)

(72) Inventor: KOHEI IMOTO, Saitama (JP)

(21) Appl. No.: 18/739,931

(22) Filed: Jun. 11, 2024

(30) Foreign Application Priority Data
Jun. 13, 2023 (JP) 2023-097242

(51) Int. Cl. G03F 7/00; B29C 59/02

(52) U.S. Cl. CPC G03F 7/707; G03F 7/0002; G03F 7/70733; B29C 59/026

(57) ABSTRACT

A substrate chuck is provided. The substrate chuck includes a plurality of attraction regions including a first attraction region and a second attraction region formed on an inner periphery side of the first attraction region, which are concentrically partitioned by partitions on a substrate holding surface, and a pressure space formed inside the substrate chuck under the first and second attraction regions and configured to displace the substrate holding surface by being applied with one of a negative pressure and a positive pressure. A height of an outer periphery side partition of the first attraction region is lower than an inner periphery side partition that partitions the first attraction region and the second attraction region, and a radius of an outer periphery side end portion of the pressure space is not larger than a neutral radius of the outer periphery side partition.

### BACKGROUND OF THE INVENTION

### Field of the Invention

The present invention relates to a substrate chuck, a lithography apparatus, and an article manufacturing method.

### Description of the Related Art

There is known a photolithography technique as a method of manufacturing an article such as a semiconductor device or a MEMS. In the photolithography technique, a pattern formed on a mold is transferred to a region (shot region) on a substrate. In this transfer process, it is important to make the positions and shapes of the pattern and the shot region match each other. Japanese Patent Laid-Open No. 2020-92178 discloses a technique of forming a partition on a substrate holding surface of a substrate chuck near the outer periphery of the substrate where distortion tends to be large and individually controlling the pressure in each of spaces partitioned by the partition, thereby correcting the distortion shape of the substrate.

Along with high integration of a semiconductor device, multilayering of circuit patterns progresses. In the multilayered substrate, various shapes of warpage may occur due to accumulation of film distortion generated at the time of film formation. In the technique disclosed in Japanese Patent Laid-Open No. 2020-92178, it is possible to correct a sharp distortion shape near the outer periphery of a substrate. However, the technique disclosed in Japanese Patent Laid-Open No. 2020-92178 is not suitable for correcting a gentle distortion shape.

### SUMMARY OF THE INVENTION

The present invention provides a technique advantageous in further improving the accuracy of correction of the shape of a substrate.

The present invention in its one aspect provides a substrate chuck for attracting and holding a substrate on a substrate holding surface, including a plurality of attraction regions including a first attraction region and a second attraction region formed on an inner periphery side of the first attraction region, which are concentrically partitioned by partitions on the substrate holding surface, and a pressure space formed inside the substrate chuck under the first attraction region and the second attraction region and configured to displace the substrate holding surface by being applied with one of a negative pressure and a positive pressure, wherein a height of an outer periphery side partition of the first attraction region is lower than an inner periphery side partition that partitions the first attraction region and the second attraction region, and a radius of an outer periphery side end portion of the pressure space is not larger than a neutral radius of the outer periphery side partition.

Further features of the present invention will become apparent from the following description of exemplary embodiments (with reference to the attached drawings).

### BRIEF DESCRIPTION OF THE DRAWINGS

FIG. 1 is a view showing the arrangement of an imprint apparatus;

FIG. 2 is a plan view of a substrate chuck in a state in which a substrate is placed;

FIG. 3 is a plan view of the substrate chuck in a state in which the substrate is removed;

FIG. 4 is a sectional view of the substrate chuck;

FIG. 5 is a view for explaining a method of attracting the substrate;

FIG. 6 is a view for explaining a method of attracting the substrate;

FIG. 7 is a view for explaining a substrate deformation method by a hollow portion;

FIG. 8 is a view for explaining the substrate deformation method by the hollow portion;

FIG. 9 is a view for explaining the substrate deformation method by the hollow portion; and

FIG. 10 is a view showing a plurality of shot regions of the substrate.

It will be understood that all the drawings are schematic views and are not always drawn in accordance with the actual scale. The dimensions of some of elements shown in the drawings are sometimes exaggerated with respect to other elements for the purpose of assisting understanding of an embodiment of the present disclosure.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

The present disclosure relates to a lithography apparatus for forming a pattern or a film on a substrate. Examples of the lithography apparatus are an imprint apparatus, a film forming apparatus (planarization apparatus), and an exposure apparatus. The imprint apparatus is an apparatus that forms a pattern on a substrate by curing an imprint material in a state in which a mold (original) is in contact with the imprint material supplied onto the substrate. The film forming apparatus is an apparatus that forms a flat film on a substrate by curing a curable composition in a state in which a flat template is in contact with the curable composition supplied onto the substrate. An exposure apparatus is an apparatus that transfers a pattern of an original to a substrate via a projection optical system. For example, the exposure apparatus exposes, via an original (reticle) as an exposure mask, a photoresist applied onto a substrate, thereby forming, on the photoresist, a latent image corresponding to the pattern of the original. Hereinafter, to provide a detailed example, an example in which the lithography apparatus is configured as an imprint apparatus will be explained.

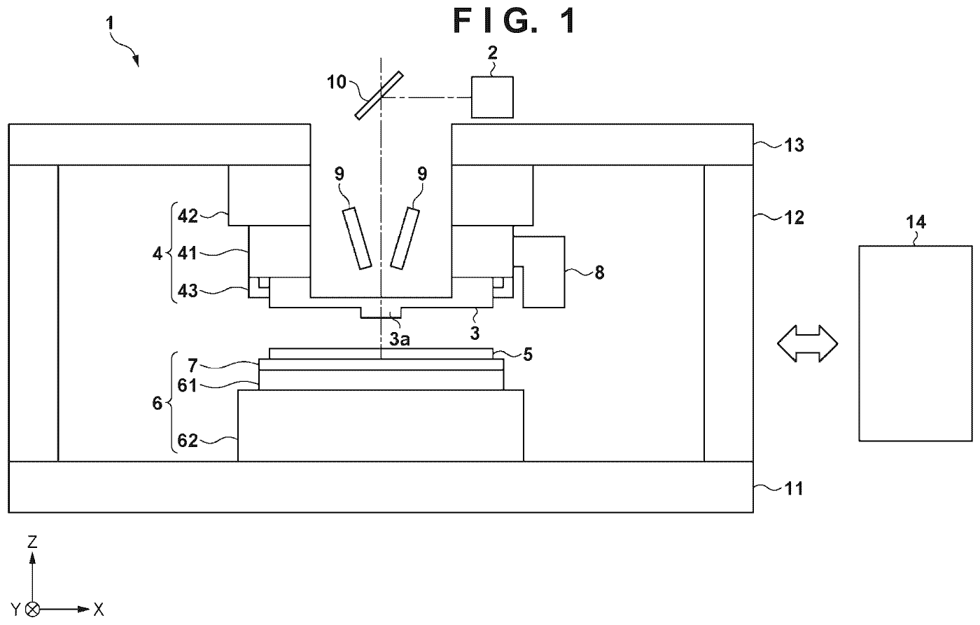

FIG. 1 is a schematic view of an imprint apparatus 1 according to the embodiment. In this specification and the accompanying drawings, directions are indicated on an XYZ coordinate system in which a horizontal plane is defined as an XY plane. In general, a substrate 5 is placed on a substrate stage 6 such that its surface is parallel to the horizontal plane (XY plane). Hence, directions orthogonal to each other in a plane along the surface of the substrate 5 will be defined as the X-axis and the Y-axis hereinafter, and a direction perpendicular to the X-axis and the Y-axis will be defined as the Z-axis. In addition, directions parallel to the X-axis, the Y-axis, and the Z-axis in the XYZ coordinate system will be defined as the X direction, the Y direction, and the Z direction, respectively, hereinafter, and a rotation direction about the X-axis, a rotation direction about the Y-axis, and a rotation direction about the Z-axis will be defined as the OX direction, the OY direction, and the OZ direction, respectively.

First, an overview of the imprint apparatus according to the embodiment will be described. The imprint apparatus is an apparatus that brings an imprint material supplied onto a substrate into contact with a mold, and applies curing energy to the imprint material, thereby forming the pattern of a cured product to which the uneven pattern of the mold is transferred.

As the imprint material, a curable composition (to be also referred to as a resin in an uncured state) to be cured by receiving curing energy is used. As the curing energy, an electromagnetic wave or heat can be used. The electromagnetic wave can be, for example, light selected from the wavelength range of 10 nm (inclusive) to 1 mm (inclusive), for example, infrared rays, visible light, or ultraviolet light. The curable composition can be a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material can be arranged, by an imprint material supply device (a supplier 8 shown in FIG. 1), on the substrate in the form of droplets or in the form of an island or film formed by connecting a plurality of droplets. The viscosity (the viscosity at 25° C.) of the imprint material can be, for example, from 1 mPa's (inclusive) to 100 mPa's (inclusive). As the material of the substrate, for example, glass, ceramic, a metal, a semiconductor, a resin, or the like can be used. A member made of a material different from that of the substrate may be formed on the surface of the substrate, as needed. The substrate is, for example, a silicon wafer, a semiconductor compound wafer, or silica glass.

The imprint apparatus 1 can include an irradiator 2 that performs light irradiation, a mold holder 4 that holds a mold 3, a substrate chuck 7 that holds the substrate 5, and the substrate stage 6 that moves the substrate chuck 7 mounted thereon. The imprint apparatus 1 can further include the supplier 8 that supplies the imprint material, an alignment optical system 9, and a controller 14.

Light emitted from the irradiator 2 is reflected by an optical part 10, passes through the mold 3, and reaches the imprint material on the substrate 5. The optical part 10 can include an optical element for adjusting the light emitted from the irradiator 2 to light suitable for an imprint process.

The mold 3 can have a rectangular outer shape. The mold 3 includes a pattern portion 3a three-dimensionally formed on a surface facing the substrate 5. The material of the mold 3 is a material such as silica glass that can transmit ultraviolet rays.

The mold holder 4 is fixed to a bridge surface plate 13 that is supported by a base surface plate 11 via columns 12. The substrate stage 6 is fixed to the base surface plate 11. The mold holder 4 can include a mold holding mechanism 41 that holds the mold 3 by vacuum suction or an electrostatic force, and a mold moving mechanism 42 that moves the mold holding mechanism 41 in the Z direction. The mold holding mechanism 41 and the mold moving mechanism 42 have an opening at the center (inside) so that the imprint material on the substrate 5 is irradiated with the light from the irradiator 2. The mold moving mechanism 42 can include, for example, an actuator such as a voice coil motor or an air cylinder. The mold moving mechanism 42 moves the mold holding mechanism 41 (mold 3) in the Z direction to bring the mold 3 into contact with the imprint material on the substrate or release the mold 3 from the imprint material on the substrate. The mold moving mechanism 42 may be configured to have a function of adjusting the position of the mold holding mechanism 41 not only in the Z direction but also in the X direction and the Y direction. In addition, the mold moving mechanism 42 may be configured to have a function of adjusting the position of the mold holding mechanism 41 in the OZ direction and a tilt function of adjusting a tilt (that is, the position in the OX and OY directions) of the mold holding mechanism 41.

The mold holder 4 can further include a mold deformation mechanism 43. The mold deformation mechanism 43 corrects the shape of the mold 3 (pattern portion 3a) by applying an external force or displacement to a side surface of the mold 3. The mold deformation mechanism 43 is configured to include, for example, a plurality of actuators to pressurize a plurality of points on each side surface of the mold 3.

The substrate stage 6 can include the substrate chuck 7, a stage driver 61 that drives the substrate chuck 7, and a surface plate 62 on which the substrate chuck 7 and the stage driver 61 are mounted. When bringing the mold 3 and the imprint material on the substrate 5 into contact with each other, the substrate 5 and the mold 3 can be aligned by moving the substrate 5 in the X direction and the Y direction using the substrate stage 6. The substrate chuck 7 attracts and holds the substrate 5 on a substrate holding surface by vacuum suction or an electrostatic action. The stage driver 61 mechanically holds the substrate chuck 7, and drives the substrate chuck 7 in the X direction and the Y direction. As the stage driver 61, for example, a linear motor can be used. The stage driver 61 may be formed by a plurality of driving systems including a coarse driving system and a fine driving system. The stage driver 61 may have a driving function of driving the substrate 5 in the Z direction, a position adjustment function of adjusting the position of the substrate 5 in the OZ direction, and a tilt function of adjusting a tilt (that is, the position in the OX and OY directions) of the substrate 5.

To measure the position of the substrate stage 6, for example, an encoder system including a scale provided on the substrate stage 6 and a head (optical device) provided in the stage driver 61 can be used. However, the present invention is not limited to this. For example, to measure the position of the substrate stage 6, an interferometer system including an interferometer and a reflecting mirror provided in the stage driver 61 may be used.

The supplier 8 supplies the imprint material onto the substrate 5. The imprint material supplied from the supplier 8 onto the substrate 5 can appropriately be selected under various conditions in a step of manufacturing a semiconductor device. The position and amount of the imprint material discharged from a discharge outlet of the supplier 8 can appropriately be decided in consideration of the thickness and density of the pattern formed in the imprint material on the substrate. To sufficiently fill the pattern formed on the mold 3 with the imprint material supplied onto the substrate, a predetermined time may elapse in a state in which the mold 3 and the imprint material are in contact with each other.

The alignment optical system 9 measures a positional shift in the X and Y directions between an alignment mark formed on the substrate 5 and an alignment mark formed on the mold 3. The position of the substrate stage 6 can be adjusted based on the measured positional shift.

The imprint apparatus 1 may further include a height measurement device (not shown) that measures the distance to the upper surface of the substrate 5. The height measurement device may be a device outside the imprint apparatus 1. In this case, data measured by the height measurement device can be transmitted to the imprint apparatus 1, and stored in a memory of the controller 14.

The controller 14 is formed by, for example, a computer including a CPU and a memory. The controller 14 comprehensively controls the operation of the imprint apparatus 1 in accordance with a program stored in the memory.

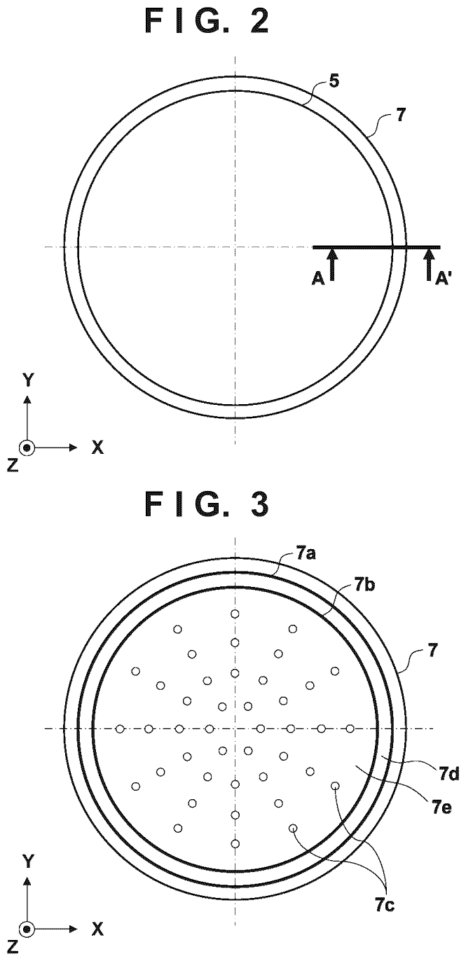

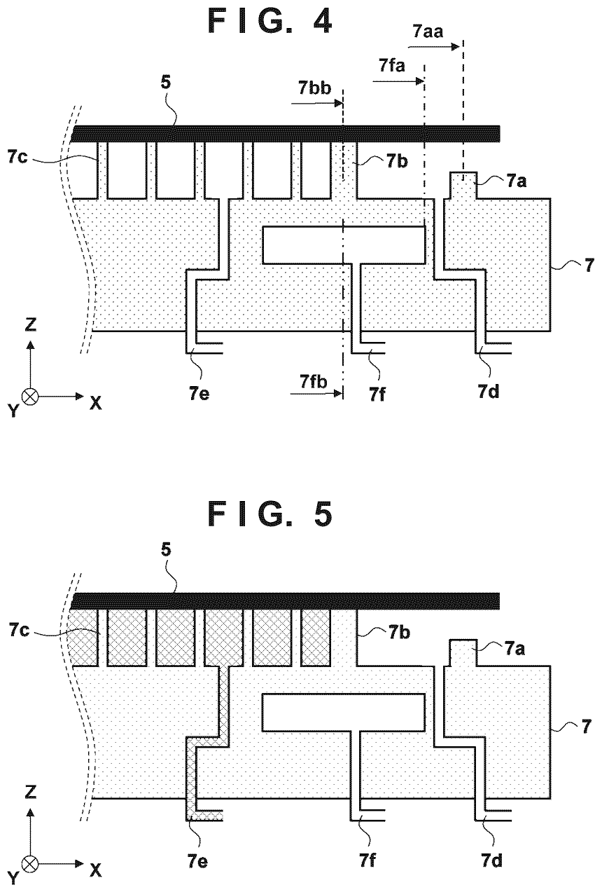

The arrangement of the substrate chuck 7 will be described with reference to FIGS. 2, 3, and 4. FIG. 2 is a plan view when viewing the substrate 5 and the substrate chuck 7 that holds the substrate 5 from above in the Z-axis direction. FIG. 3 is a plan view of the substrate chuck 7 whose substrate holding surface is exposed by removing the substrate 5 in FIG. 2. FIG. 4 is a sectional view taken along a line A-A′ shown in FIG. 2.

As shown in FIG. 3, on the surface (substrate holding surface) of the substrate chuck 7 on which the substrate 5 is placed, an outer periphery side partition 7a and an inner periphery side partition 7b formed on the inner periphery side of the outer periphery side partition 7a are formed. In a region on the inner periphery side of the inner periphery side partition 7b on the substrate holding surface, a plurality of projecting portions 7c for supporting the substrate 5 are formed. The outer periphery side partition 7a and the inner periphery side partition 7b are arranged concentrically in accordance with the shape of the substrate. Since the substrate 5 is assumed to have a circular shape, the outer periphery side partition 7a and the inner periphery side partition 7b are arranged concentrically.

### (Arrangement of Section of Substrate Chuck 7)

As shown in FIG. 4, on the substrate placement surface (substrate holding surface) of the substrate chuck 7, the height (the position in the Z direction) of the outer periphery side partition 7a is lower than the plurality of projecting portions 7c and the inner periphery side partition 7b. In an example, the difference in height between the outer periphery side partition 7a and the plurality of projecting portions 7c and inner periphery side partition 7b can fall within a range of 1 to 10 μm. Note that in FIG. 4, the difference in height between the outer periphery side partition 7a and the plurality of projecting portions 7c and inner periphery side partition 7b is deformed and drawn.

The substrate chuck 7 can include a plurality of attraction regions for attracting (sucking) the substrate 5 on the substrate holding surface. The plurality of attraction regions can include an outer periphery side attraction region 7d (first attraction region) and an inner periphery side attraction region 7e (second attraction region) formed on the inner periphery side of the outer periphery side attraction region 7d, which are concentrically partitioned by the partitions. The outer periphery side attraction region 7d is formed in a space surrounded by the outer periphery side partition 7a and the inner periphery side partition 7b. The inner periphery side attraction region 7e is formed in a space including the plurality of projecting portions 7c on the inner periphery side of the inner periphery side partition 7b.

In this embodiment, a hollow portion 7f as a disk-shaped space is formed inside the substrate chuck 7. The hollow portion 7f is a pressure space that is formed inside the substrate chuck 7 under the outer periphery side attraction region 7d and the inner periphery side attraction region 7e and is configured to displace the substrate holding surface by being applied with a negative or positive pressure. In an example, the hollow portion 7f is formed concentrically with the outer periphery side partition 7a and the inner periphery side partition 7b. This aims at deforming the substrate chuck 7 by applying a pressure to the hollow portion 7f, transmitting the deformation to the substrate 5, and thus deforming the substrate 5.

However, as shown in FIG. 4, in the outer periphery side attraction region 7d, the substrate 5 is not supported by the substrate chuck 7, and thus the deformation of the substrate chuck 7 caused by applying the pressure to the hollow portion 7f cannot be transmitted to the substrate 5. In this embodiment, to efficiently transmit the deformation of the hollow portion 7f to the substrate 5, the radius of the outer periphery side end portion of the hollow portion 7f is set to be equal to or smaller than the neutral radius of the outer periphery side partition 7a. More specifically, the hollow portion 7f is arranged so that a hollow portion outer radius 7fa as the radius of the outer edge of the hollow portion 7f is equal to or smaller than an outer periphery side partition radius 7aa as the neutral radius of the outer periphery side partition 7a.

### (Method of Attracting Substrate 5)

As shown in FIG. 5, vacuum suction of the substrate 5 to the substrate chuck 7 is implemented by evacuating the inner periphery side attraction region 7e. Referring to FIG. 5, the inner periphery side attraction region 7e represented by dark hatching (cross hatching) can include a region where the plurality of projecting portions 7c are arranged inside the inner periphery side partition 7b and an exhaust path (channel) extending through the substrate chuck 7 to the lower side.

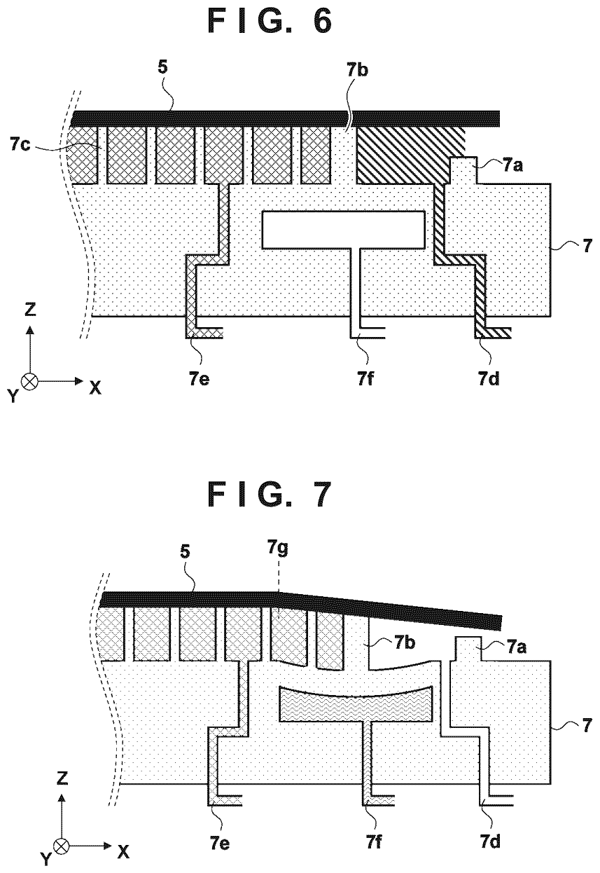

The height (the position in the Z direction) of the outer periphery side partition 7a is lower than the plurality of projecting portions 7c and the inner periphery side partition 7b. Referring to FIG. 6, the substrate 5 can also be attracted by the outer periphery side attraction region 7d represented by diagonal hatching, which is a space surrounded by the inner periphery side partition 7b and the outer periphery side partition 7a. The outer periphery side attraction region 7d also includes an exhaust path (channel) extending through the substrate chuck 7.

The hollow portion 7f also includes a channel extending through the substrate chuck 7 to the lower side. Each of the outer periphery side attraction region 7d, the inner periphery side attraction region 7e, and the hollow portion 7f is connected to a pressure controller (vacuum device) (not shown) via the channel, and the pressure in each space can individually be controlled. Note that these channels may be connected to the pressure controller from the lower side of the substrate chuck 7, or may be connected to the pressure controller by extending through another surface of the substrate chuck 7.

A central partition (not shown) that further concentrically partitions the inner periphery side attraction region 7e may be provided on the inner periphery side of the inner periphery side partition 7b. This central partition further divides the inner periphery side attraction region 7e into a plurality of regions. Each of the plurality of regions formed by the central partition is also connected to the pressure controller, and the pressure in each space can individually be controlled. The central partition is preferably arranged inside the inner periphery side end portion of the hollow portion 7f. In an example, the neutral radius of the central partition is equal to or smaller than the radius of the inner periphery side end portion of the hollow portion 7f.

Each of the plurality of projecting portions 7c arranged in the inner periphery side attraction region 7e is, for example, a pin-like projection having a diameter of 5 mm or less, and does not have a shape that partitions a region like the partition. The shape of the upper end surface of the projection may be a circular shape or a rectangular shape.

### (Substrate Deformation Method by Hollow Portion)

The controller 14 controls the shape of the substrate holding surface of the substrate chuck 7 to deform the substrate 5 held by the substrate chuck 7. A method of deforming the substrate 5 by the hollow portion 7f will be described below. As described above, the hollow portion 7f also includes the channel extending through the substrate chuck 7, and this channel is connected to the pressure controller (not shown). The channel of the hollow portion 7f may be connected to the pressure controller by extending through the lower surface of the substrate chuck 7, as shown in FIG. 6, or may be connected to the pressure controller by extending through another surface of the substrate chuck 7. The controller 14 controls the pressure in the hollow portion 7f by controlling the pressure controller.

For example, as shown in FIG. 7, the substrate chuck 7 can be deformed so that the substrate placement surface is recessed by exhausting the hollow portion 7f to lower the pressure. To the contrary, the substrate chuck 7 can be deformed so that the substrate placement surface has an upward convex shape by pressurizing the hollow portion 7f. The bending deformation of the substrate 5 may occur in accordance with the deformation of the substrate chuck 7. In an example, the substrate 5 can be deformed from a position 7g as a start point. In FIG. 7, for the sake of convenience, the substrate 5 is deformed to be bent at the position 7g. However, the substrate 5 can actually be deformed in a curved shape.

If the bending deformation of the substrate 5 occurs, in the plate bending theory, the positions of the inclined upper and lower surfaces are shifted due to the tangent components having opposite signs in the X direction. When the position of the upper surface of the substrate 5 is shifted, deviation occurs in the overlay accuracy with the pattern portion 3a. By applying the overlay deviation to a known overlay error to cancel each other, the overlay accuracy can be improved.

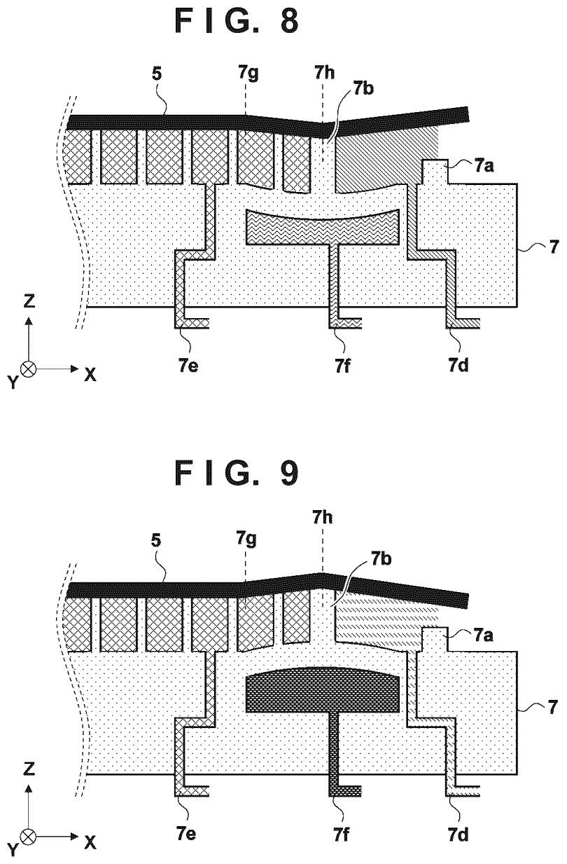

A case where deformation is added to the substrate 5 by the outer periphery side attraction region 7d will be described next with reference to FIG. 8. Referring to FIG. 8, the substrate 5 is deformed to jump upward by applying a pressure to the outer periphery side attraction region 7d (setting the outer periphery side attraction region 7d to a positive pressure). The substrate 5 is attracted and held by the inner periphery side attraction region 7e up to the position of the inner periphery side partition 7b. Therefore, the substrate 5 is deformed from a position 7h as a start point in FIG. 8 by applying a pressure to the outer periphery side attraction region 7d. As in the example shown in FIG. 8, when the pressure in the hollow portion 7f is reduced (the hollow portion 7f is set to a negative pressure) and a pressure is applied to the outer periphery side attraction region 7d (the outer periphery side attraction region 7d is set to a positive pressure), the substrate 5 can be deformed in a waveform.

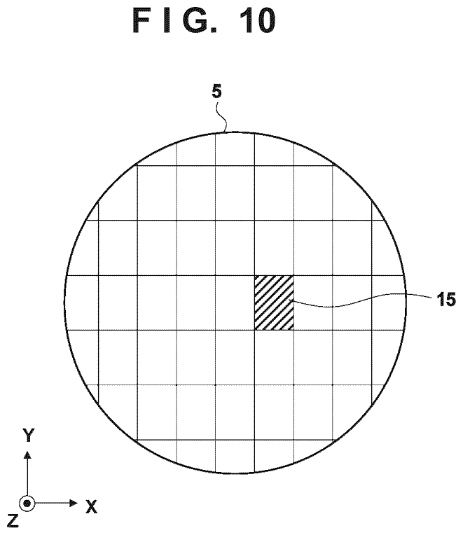

In overlay correction, the position 7g as a start point of substrate deformation by the hollow portion 7f is desirably separated from the position 7h as a start point of substrate deformation by the outer periphery side attraction region 7d. As an example, FIG. 9 shows a modification of the substrate 5 in a case where the hollow portion 7f is set to a positive pressure and the outer periphery side attraction region 7d is set to a negative pressure. It is found that deformation of the substrate 5 on the outer periphery side of the position 7g has a phase opposite to that in FIG. 8.

As described with reference to FIG. 4, in this embodiment, the hollow portion 7f is arranged so that the hollow portion outer radius 7fa is equal to or smaller than the outer periphery side partition radius 7aa. Furthermore, a neutral radius 7fb of the hollow portion 7f is desirably equal to or smaller than a neutral radius 7bb of the inner periphery side partition 7b so that uneven deformation of the hollow portion 7f becomes maximum. In a case where the neutral radius 7fb of the hollow portion 7f is equal to the neutral radius 7bb of the inner periphery side partition 7b, the deformation of the substrate 5 becomes maximum. In a case where the neutral radius 7fb of the hollow portion 7f is smaller than the neutral radius 7bb of the inner periphery side partition 7b, it is possible to set the maximum point of the deformation in a region where the substrate is held.

However, if the outer radius 7fa of the hollow portion 7f is smaller than the neutral radius 7bb of the inner periphery side partition 7b, the substrate 5 has another inflection point at a position between the positions 7g and 7h as the start points of the substrate deformation. In this arrangement, since an overlay difference that can be generated by the bending deformation of the substrate 5 is a high-order nonlinear difference curve, this is not suitable for correction of an overlay error. Therefore, the radius (outer radius 7fa) of the outer periphery side end portion of the hollow portion 7f is desirably equal to or larger than the neural radius of the inner periphery side partition 7b (7fa ≥7bb).

Note that the order of application of a pressure to the hollow portion 7f and application of a pressure to the outer periphery side attraction region 7d is not specifically limited. As exemplified above, a pressure may be applied to the outer periphery side attraction region 7d following application of a pressure to the hollow portion 7f or a pressure may be applied to the hollow portion 7f following application of a pressure to the outer periphery side attraction region 7d.

In overlay correction using the hollow portion 7f and the outer periphery side attraction region 7d, the controller 14 controls, based on distortion information obtained in advance, the pressure in each of the hollow portion 7f and the outer periphery side attraction region 7d to minimize distortion. The distortion information can be one of distortion information of an underlying pattern of the substrate 5 obtained in advance and distortion information obtained by converting the height distribution information of the substrate 5 in the Z direction. The distortion information may be acquired before the substrate 5 is loaded into the imprint apparatus 1 or acquired using a distortion measurement sensor (not shown) arranged in the imprint apparatus 1.

Pressure control of each of the hollow portion 7f and the outer periphery side attraction region 7d is desirably completed before completion of a curing step of curing the imprint material in a shot region (imprint region). However, to improve productivity, pressure control of each of the hollow portion 7f and the outer periphery side attraction region 7d and the curing step may be performed simultaneously. In this case, pressure control is desirably completed before the imprint material is completely cured.

When the substrate chuck 7 is deformed by applying a pressure to the hollow portion 7f, expansion/contraction deformation of the substrate 5 occurs due to expansion/contraction deformation of the surface of the substrate chuck 7 in the X direction caused by a frictional force between the substrate chuck 7 and the substrate 5, thereby causing unnecessary distortion of the substrate 5. To cope with the unnecessary distortion, “distortion release” control of temporarily relaxing the pressure in the inner periphery side attraction region 7e to release the distortion of the substrate 5 after the hollow portion 7f reaches a desired pressure and then returning the inner periphery side attraction region 7e to the desired pressure may be performed. To release the distortion, for example, the controller 14 applies the desired pressure to the hollow portion 7f in a state in which a negative pressure is applied to the inner periphery side attraction region 7e, temporarily releases the negative pressure in the inner periphery side attraction region 7e, and applies again the negative pressure to the inner periphery side attraction region 7e. The curing step is desirably executed after performing the distortion release control.

The substrate 5 includes a plurality of shot regions, as shown in FIG. 10, and an imprint process is performed for each of the plurality of shot regions. Pressure control of each of the hollow portion 7f and the outer periphery side attraction region 7d for correction of the overlay error can be performed using a common pressure control value for all the shot regions. However, since the overlay error may be different for each shot region, pressure control may be performed using a different pressure control value for each shot region.

Consider a case where the curing step is performed by controlling each of the hollow portion 7f and the outer periphery side attraction region 7d to the desired pressure in a first shot region 15 shown in FIG. 10 and then the imprint process is performed for the next shot region (second shot region). In this case, if the pressure in each of the hollow portion 7f and the outer periphery side attraction region 7d is controlled to a pressure different from that in the first shot region 15, unnecessary distortion may occur in the second shot region. To cope with this, before completion of the curing step of the second shot region, the controller 14 may temporarily release the negative pressure in the inner periphery side attraction region 7e. Alternatively, before completion of the curing step of the second shot region, the controller may return the pressure in the hollow portion 7f to the initial value. Alternatively, before completion of the curing step of the second shot region, the controller 14 may temporarily release the negative pressure in the inner periphery side attraction region 7e and also return the pressure in the hollow portion 7f to the initial value. This can release the unnecessary distortion of the substrate 5, thereby improving the correction accuracy of the overlay error.

### Embodiment of Article Manufacturing Method

The article manufacturing method according to the embodiment of the present invention is suitable for manufacturing an article, for example, a microdevice such as a semiconductor device or an element having a fine structure. The article manufacturing method according to this embodiment includes a step of transferring a pattern of an original to a substrate using the above-described lithography apparatus (an exposure apparatus, an imprint apparatus, a drawing apparatus, or the like), and a step of processing the substrate to which the pattern is transferred in the step. The manufacturing method also includes other known steps (oxidation, deposition, vapor deposition, doping, planarization, etching, resist removal, dicing, bonding, packaging, and the like). The article manufacturing method according to this embodiment is advantageous in at least one of the performance, quality, productivity, and production cost of the article, as compared to conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-097242, filed Jun. 13, 2023, which is hereby incorporated by reference herein in its entirety.

What is claimed is:

1. A substrate chuck for attracting and holding a substrate on a substrate holding surface, comprising:
a plurality of attraction regions including a first attraction region and a second attraction region formed on an inner periphery side of the first attraction region, which are concentrically partitioned by partitions on the substrate holding surface; and
a pressure space formed inside the substrate chuck under the first attraction region and the second attraction region and configured to displace the substrate holding surface by being applied with one of a negative pressure and a positive pressure,
wherein a height of an outer periphery side partition of the first attraction region is lower than an inner periphery side partition that partitions the first attraction region and the second attraction region, and
a radius of an outer periphery side end portion of the pressure space is not larger than a neutral radius of the outer periphery side partition.

2. The substrate chuck according to claim 1, wherein the neutral radius of the pressure space is not larger than a neutral radius of the inner periphery side partition.

3. The substrate chuck according to claim 1, wherein the radius of the outer periphery side end portion of the pressure space is not smaller than a neutral radius of the inner periphery side partition.

4. The substrate chuck according to claim 1, further comprising a central partition configured to further concentrically partition the second attraction region.

5. The substrate chuck according to claim 4, wherein a neutral radius of the central partition is not larger than a radius of an inner periphery side end portion of the pressure space.

6. The substrate chuck according to claim 1, further comprising a plurality of projecting portions formed in the second attraction region and configured to support the substrate.

7. A lithography apparatus for transferring a pattern of an original to a substrate, comprising:
a substrate chuck configured to attract and hold the substrate on a substrate holding surface; and
a controller configured to deform the substrate held by the substrate chuck by controlling a shape of the substrate holding surface of the substrate chuck,
wherein the substrate chuck includes
a plurality of attraction regions including a first attraction region and a second attraction region formed on an inner periphery side of the first attraction region, which are concentrically partitioned by partitions on the substrate holding surface, and
a pressure space formed inside the substrate chuck under the first attraction region and the second attraction region and configured to displace the substrate holding surface by being applied with one of a negative pressure and a positive pressure,
an outer periphery side partition of the first attraction region is lower than an inner periphery side partition that partitions the first attraction region and the second attraction region,
a radius of an outer periphery side end portion of the pressure space is not larger than a neutral radius of the outer periphery side partition, and
the controller deforms the substrate by individually controlling a pressure in each of the first attraction region, the second attraction region, and the pressure space.

8. The apparatus according to claim 7, wherein the controller individually controls the pressure in each of the first attraction region and the pressure space based on distortion information of the substrate.

9. The apparatus according to claim 8, wherein the controller applies a pressure to the first attraction region following application of a pressure to the pressure space.

10. The apparatus according to claim 8, wherein the controller applies a pressure to the pressure space following application of a pressure to the first attraction region.

11. The apparatus according to claim 7, wherein the controller applies a pressure to the pressure space in a state in which a negative pressure is applied to the second attraction region, temporarily releases the negative pressure in the second attraction region, and then applies again the negative pressure to the second attraction region.

12. The apparatus according to claim 7, wherein the lithography apparatus is configured as an imprint apparatus configured to perform an imprint process of forming the pattern in an imprint material on the substrate using a mold as the original.

13. The apparatus according to claim 12, wherein
the imprint process includes curing the imprint material in a state in which the imprint material and the mold are in contact with each other, and
before completion of the curing, the controller completes pressure control of the first attraction region, the second attraction region, and the pressure space.

14. The apparatus according to claim 12, wherein
the imprint process includes curing the imprint material in a state in which the imprint material and the mold are in contact with each other,
the imprint apparatus is configured to perform the imprint process for each of a plurality of shot regions formed on the substrate, and
before completion of the curing, the controller temporarily releases the negative pressure in the second attraction region in the imprint process of each shot region.

15. An article manufacturing method comprising:
forming a pattern on a substrate using a lithography apparatus defined in claim 7; and
processing the substrate with the pattern formed thereon,
wherein an article is manufactured from the processed substrate.
